(19) United States
(12) Patent Application Publication
(10) Pub. No.: US 2016/0216728 A1
(43) Pub. Date: Jul. 28, 2016

(54) ELECTRONIC DEVICE HAVING AN ELECTRICAL CONNECTION STRUCTURE USING A WIRING MEMBER AND METHOD FOR MANUFACTURING THE STRUCTURE

(71) Applicant: KABUSHIKI KAISHA TOSHIBA, Tokyo (JP)

(72) Inventors: Akihiko HAPPOYA, Ome Tokyo (JP); Yoshikazu FURUMIYA, Chigasaki Kanagawa (JP)

(21) Appl. No.: 14/835,528

(22) Filed: Aug. 25, 2015

(30) Foreign Application Priority Data
Jan. 28, 2015 (JP) 2015-014345

(51) Int. Cl. G06F 1/16; H05K 3/40; H05K 3/10; H05K 1/02; H05K 1/11

(52) U.S. Cl. CPC G06F 1/16; H05K 1/0298; H05K 1/11; H05K 1/115; H05K 3/10; H05K 3/4007

(57) ABSTRACT

An electronic device includes an insulating layer, a first conductor portion disposed in the insulating layer, a second conductor portion disposed on a surface of the insulating layer, and a wiring member disposed within the insulating layer and electrically connecting the first conductor portion and the second conductor portion. The wiring member includes a connection portion welded to the first conductor portion and an extension portion extending from the connection portion to the second conductor portion.

### CROSS-REFERENCE TO RELATED APPLICATION

This application is based upon and claims the benefit of priority from Japanese Patent Application No. 2015-014345, filed on Jan. 28, 2015, the entire contents of which are incorporated herein by reference.

### FIELD

Embodiments described herein relate generally to an electronic device having an electrical connection structure using a wiring member and a method for manufacturing the structure.

### BACKGROUND

A board in which an electronic component such as a capacitor, a resistor, and a semiconductor component is embedded is known. Such a board is referred to as a component built-in board or a semiconductor embedded board.

### DESCRIPTION OF THE DRAWINGS

FIG. 1 is a perspective view of a portable computer according to a first embodiment.

FIG. 2 is a perspective view of an SSD according to the first embodiment.

FIG. 3 is a cross-sectional view of a storage module according to the first embodiment.

FIG. 4 is a cross-sectional view of a storage component according to the first embodiment.

FIG. 5 is a cross-sectional view of a first insulating layer in which a memory element according to the first embodiment is die-bonded.

FIG. 6 is a cross-sectional view of the memory element and the first insulating layer which are bonded to each other by wire bonding according to the first embodiment.

FIG. 7 is a cross-sectional view of the memory element and a bonding wire embedded in a second insulating layer according to the first embodiment.

FIG. 8 is a cross-sectional view of the second insulating layer and the bonding wire which are ground according to the first embodiment.

FIG. 9 is a cross-sectional view of a conductive film formed on the second insulating layer according to the first embodiment.

FIG. 10 is a cross-sectional view of a third conductor pattern formed on the second insulating layer according to the first embodiment.

FIG. 11 is a cross-sectional view of a storage component according to a second embodiment.

FIG. 12 is a cross-sectional view of a memory element in which a stud bump according to the second embodiment is formed.

FIG. 13 is a cross-sectional view of the second insulating layer and the stud bump which are ground according to the second embodiment.

FIG. 14 is a cross-sectional view of a third conductor pattern formed on the second insulating layer according to the second embodiment.

FIG. 15 is a cross-sectional view of a storage component according to a third embodiment.

FIG. 16 is a cross-sectional view of the first insulating layer where wire bonding is performed according to the third embodiment.

FIG. 17 is a cross-sectional view of the second insulating layer and a bonding wire which are ground according to the third embodiment.

FIG. 18 is a cross-sectional view of the third conductor pattern formed in the second insulating layer according to the third embodiment.

### DETAILED DESCRIPTION

In the board in which the electronic component is embedded, the manufacturing time and manufacturing cost are likely to increase compared with a board on which an electronic component is mounted.

In general, according to one embodiment, an electronic device includes an insulating layer, a first conductor portion disposed in the insulating layer, a second conductor portion disposed on a surface of the insulating layer, and a wiring member disposed within the insulating layer and electrically connecting the first conductor portion and the second conductor portion. The wiring member includes a connection portion welded to the first conductor portion and an extension portion extending from the connection portion to the second conductor portion.

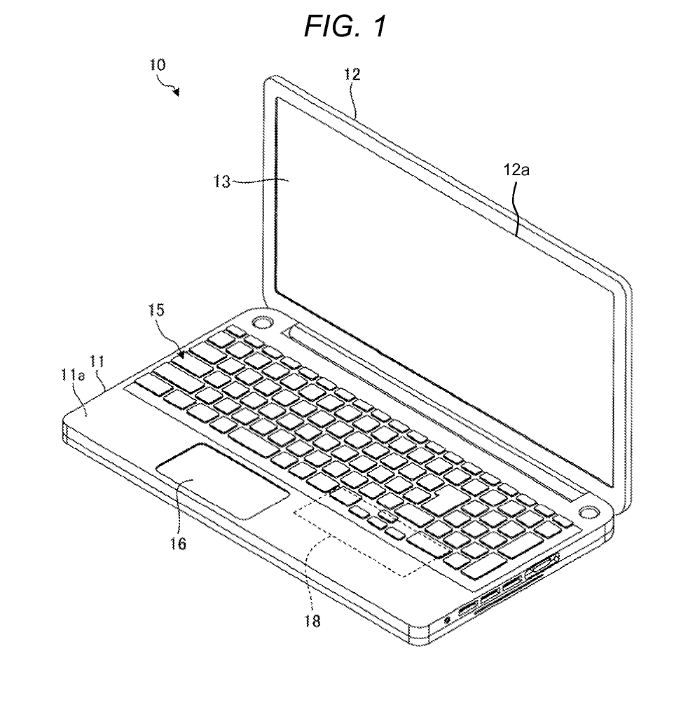

Hereinafter, a first embodiment will be described with reference to FIGS. 1 to 10. Plural components according to the embodiment may be used. With respect to components according to the embodiment and description thereof, plural expressions may be used together. With respect to the components and description, other expressions which are not shown may be used. Further, with respect to the components and description in which plural expressions are not used, other expressions may be used.

FIG. 1 is a perspective view of a portable computer 10 according to a first embodiment. The portable computer 10 may be an example of an electronic device. As shown in FIG. 1, the portable computer 10 includes a first housing 11, a second housing 12, and a display module 13. The first and second housings 11 and 12 may also be referred to as a case, a frame, and a wall, for example.

The first housing 11 includes an upper surface 11a. A keyboard 15 and a touch pad 16 are provided on the upper surface 11a. The first housing 11 accommodates a board such as a motherboard where a control processing unit (CPU) is mounted, a storage device such as a hard disk drive (HDD) or a solid state drive (SSD), and a variety of components such as a battery. As indicated by a broken line in FIG. 1, an SSD 18 is accommodated in the first housing 11. The SSD 18 may be an example of the electronic device, and may be referred to as a semiconductor device, a storage device, a board module, a module, and a component.

The second housing 12 is rotatably attached to the first housing 11 by a hinge, for example. For example, the second housing 12 is rotatable between a closing position where the second housing 12 covers the upper surface 11a of the first housing 11, and an opening position where the second housing 12 stands up from an end portion of the first housing 11.

The display module 13 is accommodated in the second housing 12. The display module 13 is exposed at a display opening 12a provided in the second housing 12. The display module 13 displays an image on a screen exposed at the display opening 12a.

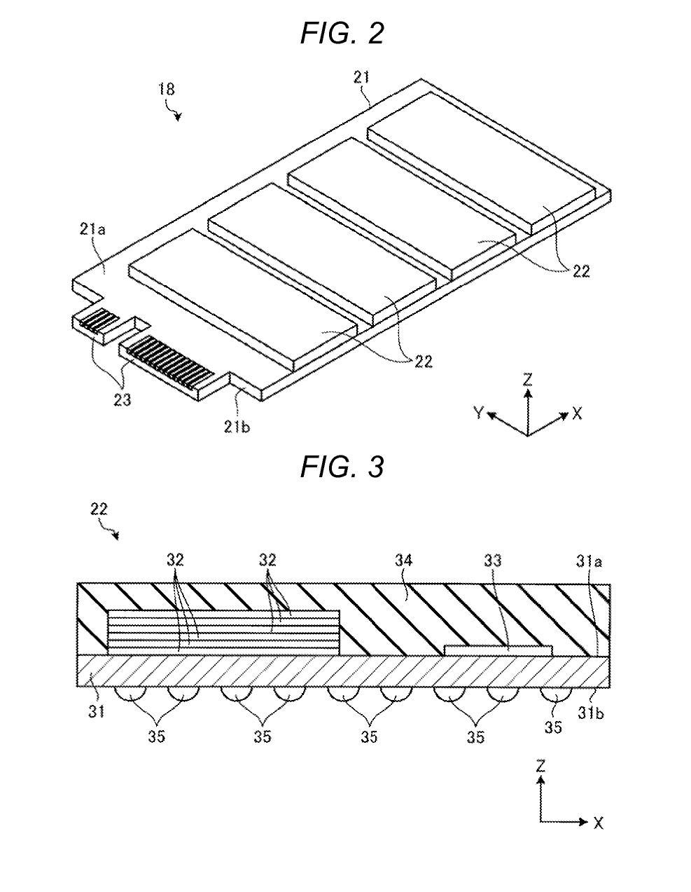

FIG. 2 is a perspective view of the SSD 18 according to the first embodiment. As shown in FIG. 2, the SSD 18 includes a circuit board 21, plural storage modules 22, and a connector 23. The SSD 18 according to the first embodiment is configured so that various components such as the circuit board 21 and the storage module 22 are exposed, but may have a housing that accommodates the components.

As shown in the plural figures, in the disclosure, an X-axis, a Y-axis, and a Z-axis are defined. The X-axis, the Y-axis, and the Z-axis are orthogonal to each other. The X-axis extends along the longitudinal edge of the SSD 18. The Y-axis extends along the lateral edge of the SSD 18. The Z-axis extends along a thickness direction of the SSD 18.

The circuit board 21 may also be referred to as a mount board and a board, for example. The circuit board 21 is a printed wiring board formed in a substantially rectangular shape (square shape). The circuit board 21 may be a different board such as a flexible printed wiring board, or may have a different shape. The circuit board 21 has a substantially flat mounting surface 21a.

The connector 23 protrudes from one end surface 21b of the circuit board 21. The connector 23 is integrally formed with the circuit board 21, for example. The connector 23 is attached to a connector provided inside the first housing 11, for example. As a result, signal transmission may be performed through the connector 23 between the SSD 18 and the portable computer 10 (host device).

Each of the storage modules 22 is a package called one package SSD, for example. The storage module 22 may be a different component such as a ball grid array (BGA) or a chip size package (CSP).

The storage modules 22 are mounted in parallel on the mounting surface 21a of the circuit board 21. The storage module 22 may be mounted on the other surface of the circuit board 21, and may be dispersedly mounted.

FIG. 3 is a cross-sectional view of the storage module 22 according to the first embodiment. As shown in FIG. 3, the storage module 22 includes a module board 31, plural storage components 32, a controller 33, a sealing portion 34, and plural bumps 35.

The module board 31 may be a printed wiring board, for example, but may be another board, for example. The module board 31 includes a mounting surface 31a and a connection surface 31b. Various components such as the storage component 32 and the controller 33 are mounted on the mounting surface 31a. The connection surface 31b is located on a side opposite to the mounting surface 31a.

The storage component 32 is an example of a board, and for example, may also be referred to as a component built-in board, a semiconductor embedded board (embedded wafer level package, EWLP), a package, and a component, for example. The storage component 32 includes a memory element, for example, and may store information. The plural storage components 32 are mounted on the mounting surface 31a of the module board 31 in a state of overlapping each other and being electrically connected to each other. A different member may be disposed between the overlapping storage components 32.

The controller 33 controls the storage component 32. The functions of the controller 33 may be achieved by a processor or hardware that executes firmware stored in the storage component 32 or a read only memory (ROM) provided in the controller 33. The controller 33 may read data from the storage component 32 or write data in the storage component 32 according to a command from a host device, for example.

The sealing portion 34 covers the mounting surface 31a of the module board 31 where the components such as the storage component 32 and the controller 33 are mounted. That is, the storage component 32 and the controller 33 are covered with the sealing portion 34. The sealing portion 34 is made of insulating synthetic resin, or may be made of a different material, for example.

The bumps 35 are provided on the connection surface 31b of the module board 31. Each of the bumps 35 is a solder ball, for example, and electrically connects an electrode of the storage module 22 formed on the connection surface 31b of the module board 31 and an electrode of the circuit board 21 formed on the mounting surface 21a of the circuit board 21.

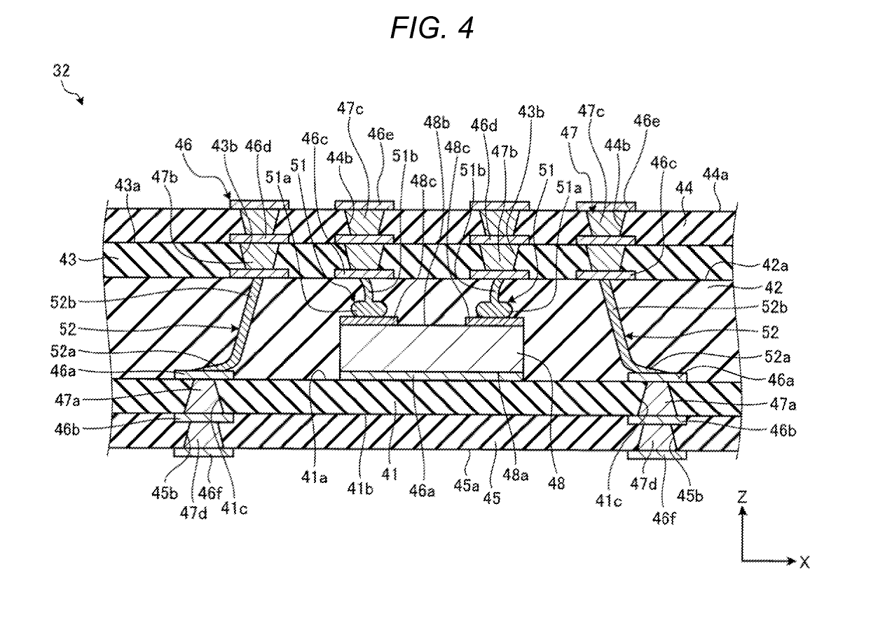

FIG. 4 is a cross-sectional view of the storage component 32 according to the first embodiment. As shown in FIG. 4, the storage component 32 includes a first insulating layer 41, a second insulating layer 42, a third insulating layer 43, a fourth insulating layer 44, a fifth insulating layer 45, plural conductor patterns 46, plural vias 47, a memory element 48, plural first wires 51, and plural second wires 52.

The first to fifth insulating layers 41 to 45 may also be referred to as a layered portion, an insulating portion, a base, a cover, a sealing portion, a layer, a plate, and a wall, for example. The conductor patterns 46 may also be referred to as a conductor, a conductive portion, a pad, an electrode, and a wiring, for example. The via 47 may be referred to as a conductor, a conductive portion, and a connecting portion, for example.

The first insulating layer 41 is made of epoxy resin containing a silicon dioxide filler, for example, and is formed in a substantially rectangular (square) plate shape. The first insulating layer 41 may be made of a different material, and may be formed in a different shape.

The first insulating layer 41 includes a first surface 41a and a second surface 41b. The first insulating layer 41 is an example of a base insulating layer. The first surface 41a and the second surface 41b are respectively formed to be substantially flat. The second surface 41b is located on a side opposite to the first surface 41a.

Plural first holes 41c are provided in the first insulating layer 41. The first holes 41c extend in a thickness direction (direction along the Z-axis) of the first insulating layer 41. The first hole 41c is a tapered hole of which the width decreases as it goes in a direction along the Z-axis from the second surface 41b. A minimum diameter of the first hole 41c is 50 μm, for example, but is not limited thereto.

The second insulating layer 42 is made of epoxy resin containing a silicon dioxide filler, for example. The epoxy resin, which is a material of the second insulating layer 42, has an ingredient and a characteristic different from those of the epoxy resin, which is a material of the first insulating layer 41. For example, the epoxy resin of the material of the second insulating layer 42 has a lower viscosity in softening, compared with the epoxy resin of the material of the first insulating layer 41. The material of the first insulating layer 41 and the material of the second insulating layer 42 may be the same.

The second insulating layer 42 is attached to the first surface 41a of the first insulating layer 41 so as to cover the first surface 41a. In other words, the second insulating layer 42 is overlaid on the first surface 41a of the first insulating layer 41.

The second insulating layer 42 includes a third surface 42a, which is substantially flat. The second insulating layer 42 is an example of an insulating layer. The third surface 42a is located on a side opposite to a surface of the second insulating layer 42 which is in contact with the first surface 41a of the first insulating layer 41. In other words, the third surface 42a is located on a side opposite to the first surface 41a of the first insulating layer 41.

The third to fifth insulating layers 43 to 45 are made of epoxy resin containing a silicon dioxide filler, for example. The epoxy resin as a material of the third to fifth insulating layers 43 to 45 may be the same as the epoxy resin as the material of the first insulating layer 41 or the second insulating layer 42, or may be different therefrom.

The third insulating layer 43 is attached to the third surface 42a of the second insulating layer 42 so as to cover the third surface 42a. The third insulating layer 43 includes a fourth surface 43a, which is substantially flat. The fourth surface 43a of the third insulating layer 43 is located on a side opposite to the third surface 42a of the second insulating layer 42.

Plural second holes 43b are provided in the third insulating layer 43. Each of the second holes 43b is a tapered hole of which width decreases as it goes in a direction along the Z-axis from the fourth surface 43a. A minimum diameter of the second hole 43b is 50 μm, for example, but is not limited thereto.

The fourth insulating layer 44 is attached to the fourth surface 43a of the third insulating layer 43 so as to cover the fourth surface 43a. The fourth insulating layer 44 includes a fifth surface 44a, which is substantially flat. The fifth surface 44a of the fourth insulating layer 44 is located on a side opposite to the fourth surface 43a of the third insulating layer 43.

Plural third holes 44b are provided in the fourth insulating layer 44. Each of the third holes 44b is a tapered hole of which width decreases as it goes in the direction along the Z-axis from the fifth surface 44a. A minimum diameter of the third hole 44b is 50 μm, for example, but is not limited thereto.

The fifth insulating layer 45 is attached to the second surface 41b of the first insulating layer 41 so as to cover the second surface 41b. The fifth insulating layer 45 includes a sixth surface 45a, which is substantially flat. The sixth surface 45a of the fifth insulating layer 45 is located on a side opposite to the second surface 41b of the first insulating layer 41.

Plural fourth holes 45b are provided in the fifth insulating layer 45. Each of the fourth holes 45b is a tapered hole of which width decreases as it goes in the direction along the Z-axis from the sixth surface 45a. A minimum diameter of the fourth hole 45b is 50 μm, for example, but is not limited thereto.

The plural conductor patterns 46 are made of copper, for example. Here, the copper represents an example of a metal containing copper. The conductor patterns 46 may be made of a different material. The plural conductive patterns 46 include plural first conductor patterns 46a, plural second conductor patterns 46b, plural third conductor patterns 46c, plural fourth conductor patterns 46d, plural fifth conductor patterns 46e, and plural sixth conductor patterns 46f. The first to sixth conductor patterns 46a to 46f form at least a part of a circuit provided in the storage component 32, and may include various patterns such as a pad, a land, and a wiring, for example.

The first conductor pattern 46a is an example of a first conductor portion and a third conductor portion. Some of the first conductor patterns 46a are provided on the first surface 41a of the first insulating layer 41 at positions corresponding to the first holes 41c. The first conductor patterns 46a are covered by the second insulating layer 42. Thus, the first conductor patterns 46a are provided inside the storage component 32.

The second conductor pattern 46b is an example of a fifth conductor portion. The plural of the second conductor patterns 46b are provided on the second surface 41b of the first insulating layer 41 at positions corresponding to the first holes 41c. The second conductor patterns 46b are covered with the fifth insulating layer 45. Thus, the second conductor patterns 46b are provided inside the storage component 32.

The third conductor patterns 46c are examples of a second conductor portion and a fourth conductor portion. The plural third conductor patterns 46c are provided on the third surface 42a of the second insulating layer 42 at positions corresponding to the second holes 43b. The third conductor patterns 46c are covered with the third insulating layer 43. Thus, the third conductor patterns 46c are provided within the storage component 32.

The plural fourth conductor patterns 46d are provided on the fourth surface 43a of the third insulating layer 43 at positions corresponding to the second holes 43b. The fourth conductor patterns 46d are covered by the fourth insulating layer 44. Thus, the fourth conductor patterns 46d are provided within the storage component 32.

The plural fifth conductor patterns 46e are provided on the fifth surface 44a of the fourth insulating layer 44 at positions corresponding to the third holes 44b. The plural sixth conductor patterns 46f are provided on the sixth surface 45a of the fifth insulating layer 45 at positions corresponding to the fourth holes 45b. The fifth and sixth conductor patterns 46e and 46f may be used as pads provided on a front surface of the storage component 32.

The plural vias 47 are made of copper, for example. Each of the vias 47 may be made of a different material. The plural vias 47 include plural first vias 47a, plural second vias 47b, plural third vias 47c, and plural fourth vias 47d. The first via 47a is an example of a via.

The first via 47a is provided in the first insulating layer 41. The first via 47a is a conductor filled in the first hole 41c, or a film of a conductor formed on an inner surface of the first hole 41c. Thus, the first via 47a is formed in a tapered shape of which width decreases as it goes in a direction along the Z-axis from the second surface 41b. The first via 47a electrically connects the first conductor pattern 46a and the second conductor pattern 46b.

The second via 47b is provided in the third insulating layer 43. The second via 47b is a conductor filled in the second hole 43b, or a film of a conductor formed on an inner surface of the second hole 43b. Thus, the second via 47b is formed in a tapered shape of which width decreases as it goes in a direction along the Z-axis from the fourth surface 43a. The second via 47b electrically connects the third conductor pattern 46c and the fourth conductor pattern 46d.

The third via 47c is provided in the fourth insulating layer 44. The third via 47c is a conductor filled in the third hole 44b, or a film of a conductor formed on an inner surface of the third hole 44b. Thus, the third via 47c is formed in a tapered shape of which width decreases as it goes in a direction along the Z-axis from the fifth surface 44a. The third via 47c electrically connects the fourth conductor pattern 46d and the fifth conductor pattern 46e.

The fourth via 47d is provided in the fifth insulating layer 45. The fourth via 47d is a conductor filled in the fourth hole 45b, or a film of a conductor formed on an inner surface of the fourth hole 45b. Thus, the fourth via 47d is formed in a tapered shape of which width decreases as it goes in a direction along the Z-axis from the sixth surface 45a. The fourth via 47d electrically connects the second conductor pattern 46b and the sixth conductor pattern 46f.

The memory element 48 is an example of an electronic component, and for example, may also be referred to as a built-in component, a semiconductor component, an element, a chip, and a component, for example. The electronic component is not limited to the memory element 48, and for example, may be various components called an integrated circuit, an LSI, or a bare chip.

The memory element 48 is, for example, a NAND-type flash memory. The memory element 48 is not limited to the NAND-type flash memory, and for example, may be a different memory such as a resistance random access memory (ReRAM) or a ferroelectric random access memory (FeRAM).

The memory element 48 is embedded in the second insulating layer 42 in a state of being attached to the first surface 41a of the first insulating layer 41. That is, the memory element 48 is covered with the second insulating layer 42. The memory element 48 includes an attachment surface 48a, a connection surface 48b, and plural electrodes 48c.

The attachment surface 48a is bonded to one of the first conductor patterns 46a formed in the first insulating layer 41 by die bonding, for example. In other words, the attachment surface 48a is attached to the first surface 41a of the first insulating layer 41. The attachment surface 48a may be directly attached to the first surface 41a, or may be attached thereto by a different method.

The connection surface 48b is located on a side opposite to the attachment surface 48a. The plural electrodes 48c are provided on the connection surface 48b. The electrode 48c is an example of a first conductor portion, and for example, may also be referred to as a terminal portion, a conductive portion, and a pad, for example. The connection surface 48b and the electrodes 48c are covered with the second insulating layer 42. Thus, the electrodes 48c are provided within the storage component 32.

The first wire 51 is an example of a wiring member, a first wire, and a conductive member. The second wire 52 is an example of a wiring member and a second wiring member. The first and second wires 51 and 52 may also be referred to as a conductor portion, a connection portion, a bonding wire, a wire member, and a wiring, for example.

The first and second wires 51 and 52 are bonding wires made of copper. The copper is an example of a metal containing copper. The first and second wires 51 and 52 may be made of a different conductor such as an alloy containing copper, gold, a silver alloy, or an aluminum alloy. The first and second wires 51 and 52 have flexibility.

In the embodiment, the materials of the first and second wires 51 and 52 are the same as the material of the conductor patterns 46 and the material of the vias 47. However, a crystalline structure of the first and second wires 51 and 52 is different from a crystalline structure of the conductor patterns 46 and the vias 47.

The first and second wires 51 and 52 are formed by performing melting, casting by ingotting, rolling, wire-drawing, heat treatment, and winding for the copper which is a raw material, for example. On the other hand, the conductor patterns 46 and the vias 47 are formed by electroplating or non-electroplating, for example. Thus, the crystalline structure of the first and second wires 51 and 52 becomes different from the crystalline structure of the conductor patterns 46 and the vias 47.

The first wire 51 is embedded in the second insulating layer 42. Thus, the first wire 51 is provided within the storage component 32. One end portion of the first wire 51 is electrically connected to the corresponding electrode 48c of the memory element 48. The other end portion of the first wire 51 is electrically connected to the corresponding third conductor pattern 46c. That is, the first wire 51 electrically connects the electrode 48c of the memory element 48 and the corresponding third conductor pattern 46c.

The first wire 51 includes a first connection portion 51a and a first extension portion 51b. The first connection portion 51a is an example of a first connection portion and a connection portion, and may also be referred to as a ball bonding portion, an end portion, a junction, an adhesive portion, a bonding portion, and a flat portion, for example. The first extension portion 51b is an example of a first extension portion and an extension portion, and for example, may also be referred to as a line portion, a protrusion portion, or an intervening portion.

The first connection portion 51a is provided at one end portion of the first wire 51. The first connection portion 51a is formed by so-called first bonding (ball bonding), for example, and has a substantially disc shape. The first connection portion 51a is welded to the electrode 48c of the memory element 48, for example, so as to be bonded to the electrode 48c. Thus, the first connection portion 51a is electrically connected to the electrode 48c.

The first extension portion 51b is disposed between the first connection portion 51a and the third conductor pattern 46c. The first extension portion 51b extends from the first connection portion 51a toward the third conductor pattern 46c. An end portion of the first extension portion 51b, which is the other end portion of the first wire 51, is electrically connected to the third conductor pattern 46c.

The first extension portion 51b extends in a direction intersecting with a normal direction of the first surface 41a of the first insulating layer 41. In other words, the first extension portion 51b extends in a direction inclined with respect to the normal direction of the first surface 41a of the first insulating layer 41. The first extension portion 51b is bent in a curved shape. The first extension portion 51b may be bent in at least one point, or may extend in a linear shape.

The first extension portion 51b is formed in a cylindrical shape having a substantially constant diameter. The diameter of the first extension portion 51b is an example of the width of the first extension portion. The first extension portion 51b may be formed in a different shape. In this case, the width of the first extension portion 51b refers to a maximum width of the first extension portion 51b in a direction orthogonal to a direction in which the first extension portion 51b extends.

The diameter of the first extension portion 51b is 20 μm, for example. That is, the diameter of the first extension portion 51b is smaller than the minimum diameters of the first to fourth holes 41c, 43b, 44b, and 45b. Further, the diameter of the first extension portion 51b is smaller than the minimum diameters of the first to fourth vias 47a to 47d. The diameter of the first extension portion 51b is not limited to the above-described value.

The width of the first connection portion 51a is larger than the diameter (width) of the first extension portion 51b. The width of the first connection portion 51a refers to a maximum width of the first connection portion 51a in a direction (XY plane) orthogonal to a thickness direction (direction along the Z-axis) of the first connection portion 51a. The first connection portion 51a is formed to be flat compared with the first extension portion 51b. A contact area between the first connection portion 51a and the electrode 48c of the memory element 48 may be larger than a cross-sectional area of the first extension portion 51b orthogonal to the direction in which the first extension portion 51b extends.

The second wire 52 is embedded in the second insulating layer 42. Thus, the second wire 52 is provided within the storage component 32. One end portion of the second wire 52 is electrically connected to the corresponding first conductor pattern 46a. The other end portion of the second wire 52 is electrically connected to the corresponding third conductor pattern 46c. That is, the second wire 52 electrically connects the first conductor pattern 46a and the corresponding third conductor pattern 46c.

The second wire 52 includes a second connection portion 52a and a second extension portion 52b. The second connection portion 52a is an example of a second connection portion and a connection portion, and may also be referred to as a stitch bonding portion, an end portion, a junction, an adhesive portion, a bonding portion, and a flat portion, for example. The second extension portion 52b is an example of a second extension portion and an extension portion, and for example, may also be referred to as a line portion, a protrusion portion, or an intervening portion.

The second connection portion 52a is provided at one end portion of the second wire 52. The second connection portion 52a is formed by so-called second bonding (stitch bonding), for example, and has a substantially flat shape. The second connection portion 52a is welded to the first conductor pattern 46a, for example, to be bonded to the first conductor pattern 46a. Thus, the second connection portion 52a is electrically connected to the first conductor pattern 46a.

The second extension portion 52b is disposed between the second connection portion 52a and the third conductor pattern 46c. The second extension portion 52b extends from the second connection portion 52a toward the third conductor pattern 46c. An end portion of the second extension portion 52b, which is the other end portion of the second wire 52, is electrically connected to the third conductor pattern 46c.

The second extension portion 52b extends in a direction intersecting the normal direction of the first surface 41a of the first insulating layer 41. In other words, the second extension portion 52b extends in a direction inclined with respect to the normal direction of the first surface 41a of the first insulating layer 41. The second extension portion 52b is bent in a curved shape. The second extension portion 52b may be bent in at least one point, or may extend in a linear shape.

The second extension portion 52b is formed in a cylindrical shape having a substantially constant diameter. The second extension portion 52b may be formed in a different shape. In this case, the width of the second extension portion 52b refers to a maximum width of the second extension portion 52b in a direction orthogonal to a direction where the second extension portion 52b extends.

The diameter of the second extension portion 52b is 20 μm, for example. That is, the diameter of the second extension portion 52b is smaller than the minimum diameters of the first to fourth holes 41c, 43b, 44b, and 45b. Further, the diameter of the second extension portion 52b is smaller than the minimum diameters of the first to fourth vias 47a to 47d. The diameter of the second extension portion 52b is not limited to the above-described value.

The width of the second connection portion 52a is larger than the diameter (width) of the second extension portion 52b. The width of the second connection portion 52a refers to a maximum width of the second connection portion 52a in a direction (XY plane) orthogonal to a thickness direction (direction along the Z-axis) of the second connection portion 52a. The second connection portion 52a is formed to be flat compared with the second extension portion 52b. A contact area between the second connection portion 52a and the first conductor pattern 46a may be larger than a cross-sectional area of the second extension portion 52b orthogonal to the direction where the second extension portion 52b extends.

A distance between the connection surface 48b of the memory element 48 and the third surface 42a of the second insulating layer 42 in the direction along the Z-axis is longer than the maximum width (diameter) of the first extension portion 51b of the first wire 51. Similarly, a distance between the first surface 41a of the first insulating layer 41 and the third surface 42a of the second insulating layer 42 in the direction along the Z-axis is longer than the maximum width (diameter) of the second extension portion 52b of the second wire 52.

On the other hand, the thicknesses of the first, third, fourth, and fifth insulating layers 41, 43, 44, and 45 are the same as or smaller than the maximum width of each via 47. The thickness of the first insulating layer 41 refers to a distance between the first surface 41a and the second surface 41b in the direction along the Z-axis. The maximum width of the via 47 refers to a maximum width of the via 47 in a direction (XY plane) orthogonal to a depth direction (direction along the Z-axis) of the via 47.

Hereinafter, a part of a manufacturing method of the storage component 32 will be described with reference to FIGS. 4 to 10. The storage component 32 is not limited to the method which will be described below, and may be manufactured through a different method.

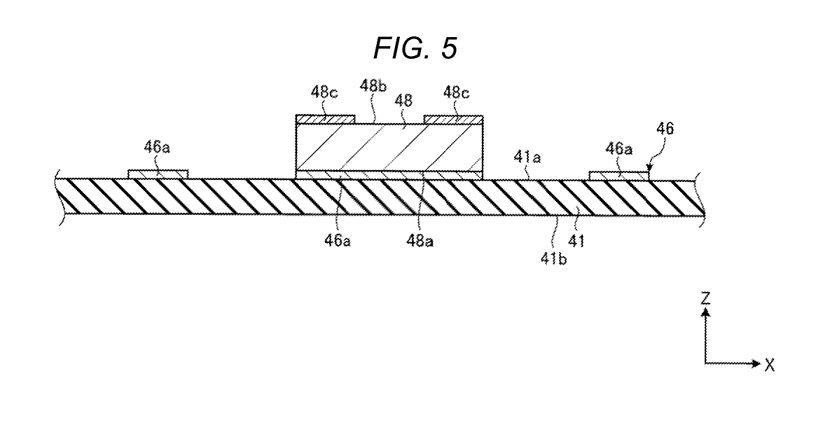

FIG. 5 is a cross-sectional view of the first insulating layer 41 where the memory element 48 of the first embodiment is subjected to die-bonding. As shown in FIG. 5, first, the first conductor pattern 46a is formed on the first surface 41a of the first insulating layer 41, and the memory element 48 is attached thereto. The first insulating layer 41 may also be referred to as a base substrate.

The first conductor pattern 46a is formed by partially removing a copper film formed on the first surface 41a by electroplating or non-electroplating by etching, for example. The first conductor pattern 46a may be formed by a different method. As described above, the memory element 48 is attached to the first conductor pattern 46a by die bonding, for example.

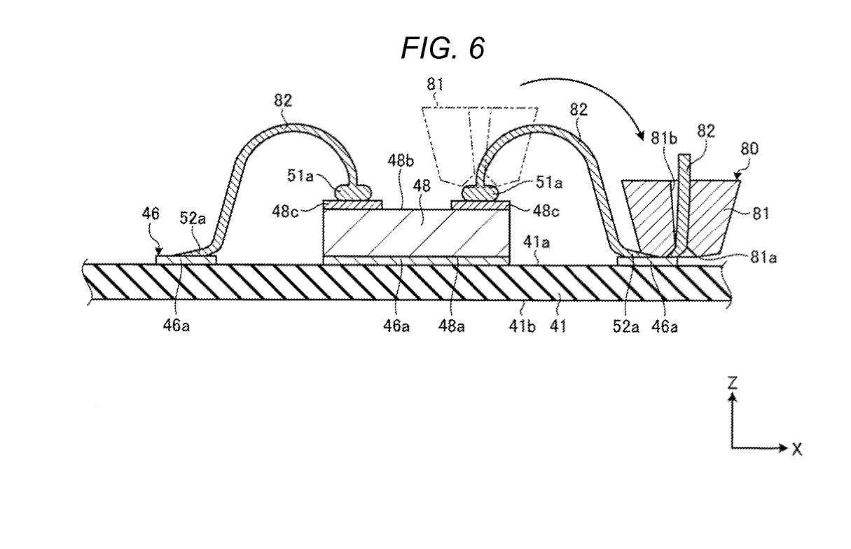

FIG. 6 is a cross-sectional view of the memory element 48 and the first insulating layer 41 which are bonded to each other by wire bonding in the first embodiment. The electrode 48c of the memory element 48 and the first conductor pattern 46a formed in the first insulating layer 41 are electrically connected to each other by wire bonding.

As shown in FIG. 6, the wire bonding between the electrode 48c and the first conductor pattern 46a is performed by a capillary 81 of a wire bonding device 80. The capillary 81 includes a tip 81a and an insert hole 81b, which is opened through the tip 81a. A bonding wire 82 passes through the insert hole 81b. The bonding wire 82 is made of copper, and forms the first wire 51 and the second wire 52, as described below.

First, for example, a tip of the bonding wire 82 that protrudes from the tip 81a of the capillary 81 is melted to form a ball. A maximum width of the ball is larger than the diameter of the bonding wire 82.

The capillary 81 presses the ball against the electrode 48c of the memory element 48 while applying heat, ultrasonic waves, and pressure to the ball of the bonding wire 82. As a result, the ball of the bonding wire 82 collapses and is bonded to the electrode 48c. The ball of the bonding wire 82 bonded to the electrode 48c forms the first connection portion 51a of the first wire 51. In this way, the bonding wire 82 is bonded to the electrode 48c by the first bonding (ball bonding). FIG. 6 shows the capillary 81 that performs the first bonding by a double dot chain line.

Next, the capillary 81 moves while drawing the bonding wire 82 to bend the bonding wire 82. The wire bonding device 80 moves the capillary 81 according to a program, for example, to bend the bonding wire 82 in a desired shape.

Then, the capillary 81 presses the bonding wire 82 against the first conductor pattern 46a while applying heat, ultrasonic waves, and pressure to the bonding wire 82. As a result, the bonding wire 82 collapses and is bonded to the first conductor pattern 46a. A portion of the bonding wire 82 bonded to the first conductor pattern 46a forms the second connection portion 52a of the second wire 52. In this way, the bonding wire 82 is bonded to the first conductor pattern 46a by the second bonding (stitch bonding). FIG. 6 shows the capillary 81 that performs the second bonding by a solid line. The capillary 81 performs the stitch bonding and tail bonding, to thereby cause the bonding wire 82 to protrude from the tip 81a.

The bonding wire 82 may be bonded to the first conductor pattern 46a by the first bonding, and may be bonded to the electrode 48c by the second bonding. Further, the bonding wire 82 may be bonded to the first conductor pattern 46a by the stitch bonding, and may also be bonded to the electrode 48c by the stitch bonding.

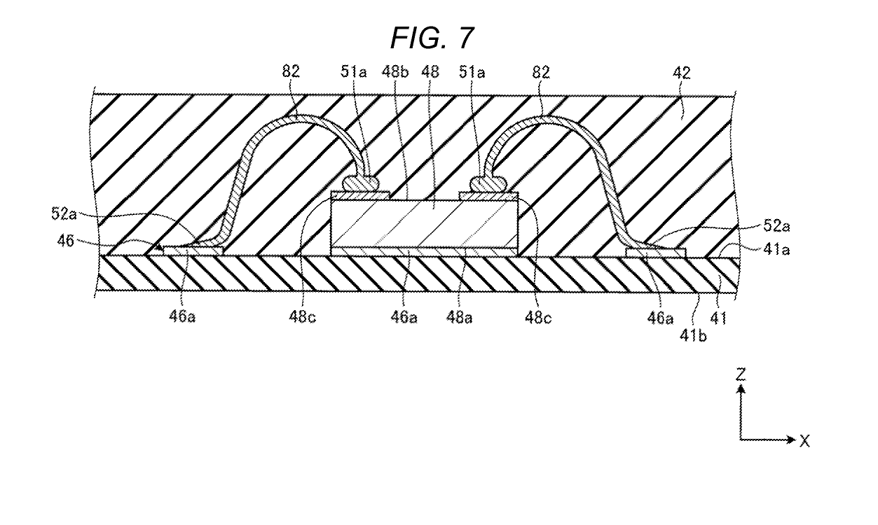

FIG. 7 is a cross-sectional view of the memory element 48 and the bonding wire 82 embedded in the second insulating layer 42 according to the first embodiment. As shown in FIG. 7, as the second insulating layer 42 is formed, the memory element 48 and the bonding wire 82 are embedded in the second insulating layer 42.

First, epoxy resin (hereinafter, referred to as a resin material) as a material of the second insulating layer 42, which is softened by heating, is supplied onto the first surface 41a of the first insulating layer 41. The resin material is an example of an insulator. As the softened resin material is supplied, the first surface 41a, the memory element 48, and the bonding wire 82 are covered with the resin material.

The resin material is supplied to the first surface 41a in a state where the bonding wire 82 bonded to the electrode 48c extends from the electrode 48c of the memory element 48 attached to the first surface 41a of the first insulating layer 41. The resin material has a relatively low viscosity at the softening. Thus, the bonding wire 82 is prevented from being bent due to the supplied resin material.

The method of supplying the resin material is not limited thereto. For example, in a state where a sheet of the resin material before softening is placed on the first surface 41a of the first insulating layer 41, the sheet of the resin material may be heated to be softened.

The resin material is cured in a state where the first surface 41a of the first insulating layer 41, the memory element 48, and the bonding wire 82 are covered with the resin material. As a result, the second insulating layer 42 is formed of the resin material. Here, a part of the bonding wire 82 may be exposed.

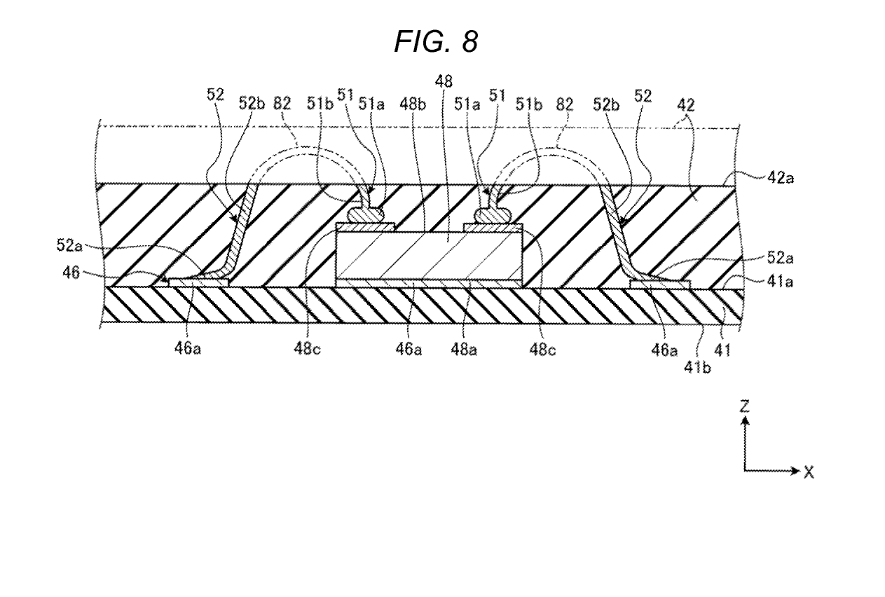

FIG. 8 is a cross-sectional view of the second insulating layer 42 and the bonding wire 82 which are ground according to the first embodiment. As shown in FIG. 8, in a state where the memory element 48 and the bonding wire 82 are covered by the second insulating layer 42, a part of the second insulating layer 42 is removed by grinding, for example.

A part (intermediate portion) of the bonding wire 82 between a portion thereof connected to the electrode 48c and a portion thereof connected to the first conductor pattern 46a, in addition to the second insulating layer 42, is removed by grinding. As a result, the bonding wire 82 is divided into the first wire 51 and the second wire 52. In other words, as the part of the bonding wire 82 is removed, the first wire 51 and the second wire 52 are formed by the bonding wire 82. FIG. 8 shows the removed parts of the second insulating layer 42 and the bonding wire 82 by double dot chain lines.

As the second insulating layer 42 is ground, the third surface 42a is formed in the second insulating layer 42. In other words, as a part of the cured resin material is removed, the second insulating layer 42 having the third surface 42a is formed by the resin material. The end portion of the first extension portion 51b of the first wire 51 and the end portion of the second extension portion 52b of the second wire 52 are exposed on the third surface 42a.

Then, oxide layers formed in the end portion of the first extension portion 51b of the first wire 51 and the end portion of the second extension portion 52b of the second wire 52 exposed to the third surface 42a are removed. The oxide layers are removed by flash etching, for example.

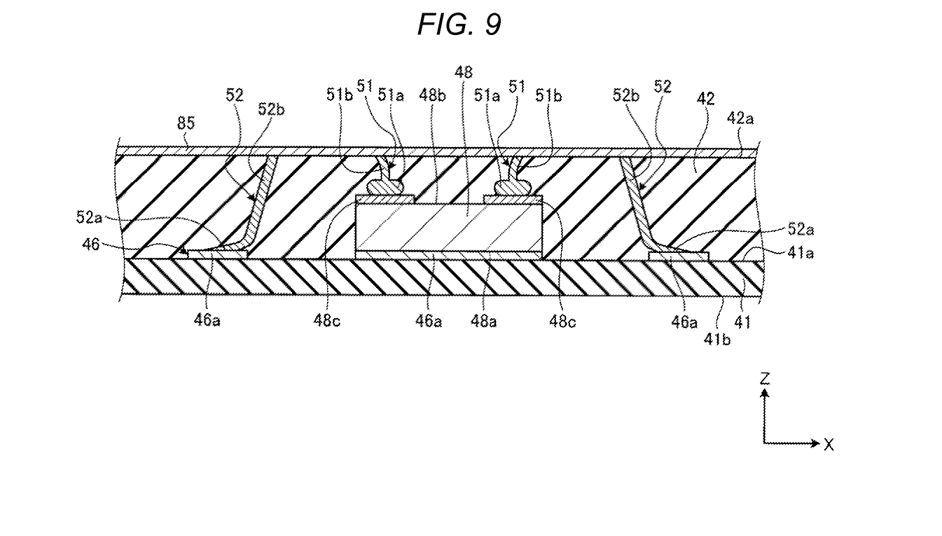

FIG. 9 is a cross-sectional view of a conductor film 85 formed on the third surface 42a of the second insulating layer 42 in the first embodiment. As shown in FIG. 9, the conductor film 85 is formed on the third surface 42a of the second insulating layer 42 by electroplating or non-electroplating, for example. The conductor film 85 is not necessarily formed by these methods, and for example, may be formed by a different method such as sputtering. The conductor film 85 is a copper film, for example, and forms the third conductor pattern 46c.

The conductor film 85 is precipitated into the end portion of the first extension portion 51b of the first wire 51 and the end portion of the second extension portion 52b of the second wire 52 exposed to the third surface 42a of the second insulating layer 42. Thus, the conductor film 85 is electrically connected to the first extension portion 51b and the second extension portion 52b.

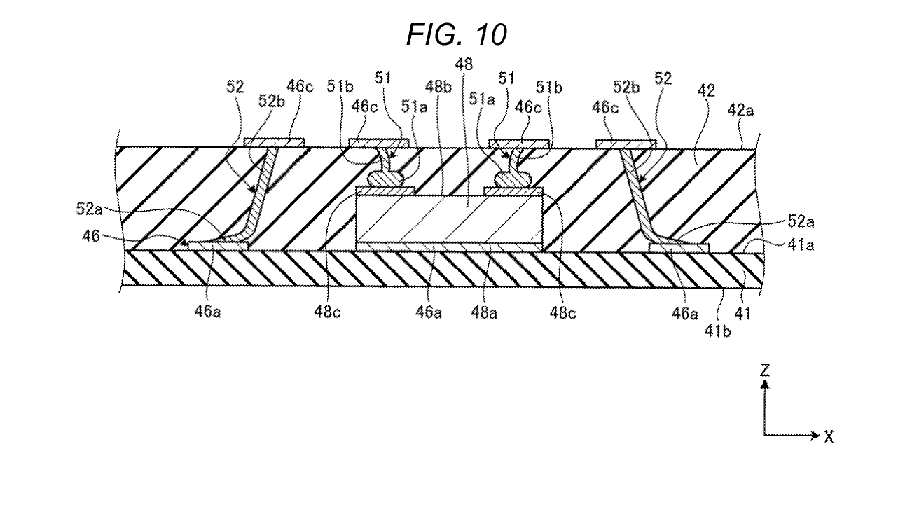

FIG. 10 is a cross-sectional view of the third conductor patterns 46c formed on the third surface 42a of the second insulating layer 42 according to the first embodiment. As shown in FIG. 10, the conductor film 85 is partially removed by etching, for example. As the conductor film 85 is partially removed, the third conductor patterns 46c are formed of the conductor film 85.

Then, formation of the third to fifth insulating layers 43 to 45, formation of the second, fourth, fifth, and sixth conductor patterns 46b, 46d, 46e, and 46f, and formation of the first to fourth holes 41c, 43b, 44b, and 45b, and formation of each via 47 are sequentially performed. The third to fifth insulating layers 43 to 45 are formed by supplying epoxy resin containing a softened silicon dioxide filler, for example. The second, fourth, fifth, and sixth conductor pattern 46b, 46d, 46e, and 46f are formed by partially removing a copper film formed by electroplating or non-electroplating by etching, for example. The first to fourth holes 41c, 43b, 44b, and 45b are formed by a laser beam such as a CO₂ laser or a YAG laser, or by a drill, for example. Each via 47 is formed by electroplating or non-electroplating, for example. Through the above-described processes, the storage component 32 in FIG. 4 is formed.

In the portable computer 10 according to the first embodiment, the first wire 51 electrically connects the electrode 48c of the memory element 48 and the third conductor pattern 46c provided on the third surface 42a of the second insulating layer 42. In this way, since the conductor portions of the different layers are connected to each other by the first wire 51, for example, compared with a case where a via or a post for interlayer connection, the manufacturing time and manufacturing cost of the storage component 32 are reduced.

Further, the diameter of the first extension portion 51b of the first wire 51 is smaller than the diameter of the via 47. Thus, as the wiring of the storage component 32 is formed by the first wire 51, it is easy to set the wiring of the storage component 32 with high density.

In addition, the first wire 51 is formed by the bonding wire 82 embedded in the second insulating layer 42. Thus, for example, compared with a via or a post formed by plating, a production yield can be improved.

Furthermore, the first connection portion 51a of the first wire 51 is bonded to the electrode 48c of the memory element 48 by the ball bonding. Thus, for example, compared with a case where a via or a post connected to the electrode 48c is formed by plating, the electrode 48c is suppressed from being damaged.

Further, as the memory element 48 is built in the storage component 32, the mounting of the storage component 32 can be easily performed with high density, and electromagnetic-shielding of the memory element 48 can be easily performed. Thus, the memory element 48 becomes strong against shock, resistance of the memory element 48 against heat is improved, and cooling of the memory element 48 becomes easier.

The second wire 52 electrically connects the first conductor pattern 46a of the first surface 41a and the third conductor pattern 46c of the third surface 42a. In this way, since the conductor portions of the different layers are connected to each other by the second wire 52, for example, compared with a case where a via or a post for interlayer connection, the manufacturing time and manufacturing cost of the storage component 32 can be reduced.

The electrode 48c and the third conductor pattern 46c are connected by the first wire 51. Thus, for example, compared with a case where a via or a post for interlayer connection is formed, a conductor portion (the first extension portion 51b of the first wire 51) having a maximum width shorter than the distance between the connection surface 48b of the memory element 48 and the third surface 42a of the second insulating layer 42 is obtained with a relatively simple configuration, or by a relatively easy method, for example.

Since the first to fourth holes 41c, 43b, 44b, and 45b in which the vias 47 for interlayer connection are formed by a laser beam or a drill, the holes extend in the direction along the Z-axis. However, as in the embodiment, as the electrode 48c and the third conductor pattern 46c are connected by the first wire 51, a conductor portion (the first extension portion 51b of the first wire 51) that extends in a direction intersecting with a normal direction may be relatively easily formed. Thus, for example, compared with a case where a via or a post for interlayer connection is formed, the degree of freedom of the wiring of the storage component 32 increases.

The epoxy resin which is the material of the second insulating layer 42 has a low viscosity in softening, compared with the epoxy resin which is the material of the first insulating layer 41. Thus, when the second insulating layer 42 is formed, the bonding wire 82 that forms the first wire 51 is suppressed from being bent.

The third conductor pattern 46c and the first wire 51 are formed by copper, respectively. Thus, the end portion of the first extension portion 51b of the first wire 51, and the third conductor pattern 46c are electrically connected to each other easily and reliably.

In the first embodiment, the first wire 51 is formed by the bonding wire 82 that connects the electrode 48c of the memory element 48 and the first conductor pattern 46. However, the first wire 51 is not necessarily formed by this method, and for example, may be formed by the bonding wire 82 that connects the electrode 48c of one memory element 48 and the electrode 48c of another memory element 48.

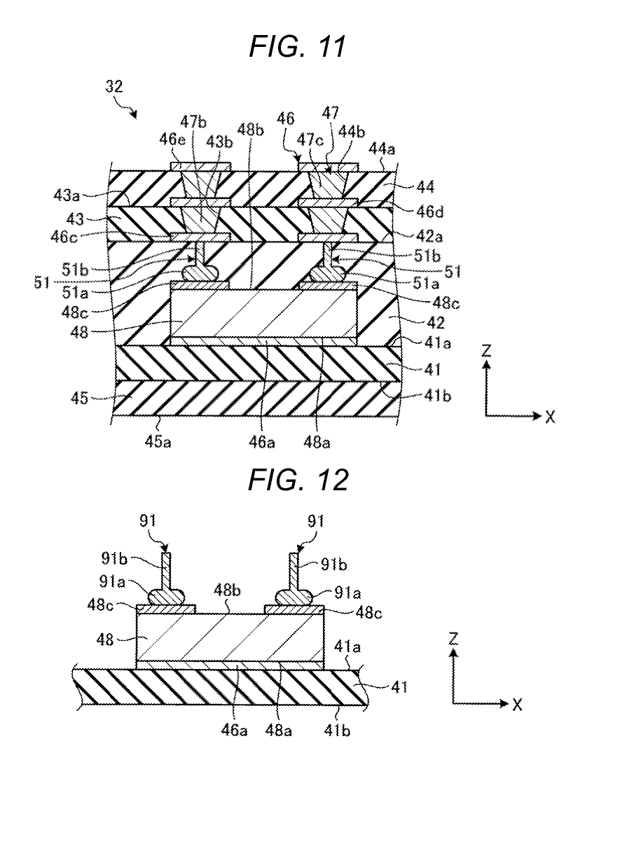

Hereinafter, a second embodiment will be described with reference to FIG. 11 to FIG. 14. In the following plural embodiments, the same reference numerals as those of the above-described components are given to components having the same functions as those of the above-described components, and description thereof may not be repeated. Further, the components having the same reference numerals are not necessarily common in the entire functions and properties, and may have different functions and properties in different embodiments.

FIG. 11 is a cross-sectional view of the storage component 32 according to the second embodiment. As shown in FIG. 11, the storage component 32 of the second embodiment includes the first wire 51.

In the second embodiment, the first extension portion 51b of the first wire 51 extends from the first connection portion 51a in a linear shape in the normal direction (direction along the Z-axis direction) of the first surface 41a of the first insulating layer 41. The first extension portion 51b is not limited thereto.

Hereinafter, a part of a manufacturing method of the storage component 32 according to the second embodiment will be described. The storage component 32 is not limited to the method described below, and may be manufactured through a different method.

FIG. 12 is a cross-sectional view of the memory element 48 where a stud bump 91 according to the second embodiment is formed. As shown in FIG. 12, the stud bump 91 is formed on the electrode 48c of the memory element 48.

The stud bump 91 is formed as the bonding wire 82 ball-bonded to the electrode 48c by the capillary 81 of the wire bonding device 80 is torn off. Thus, the stud bump 91 is an example of the bonding wire 82 and a wiring member. The stud bump 91 is not necessarily formed by this method, and may be formed by a different method.

The stud bump 91 includes a bonding portion 91a and a protrusion portion 91b. The bonding portion 91a is an end portion of the stud bump 91 ball-bonded to the electrode 48c, and forms the first connection portion 51a of the first wire 51. The protrusion portion 91b is a portion that extends in the direction along the Z-axis from the bonding portion 91a, and forms the first extension portion 51b of the first wire 51.

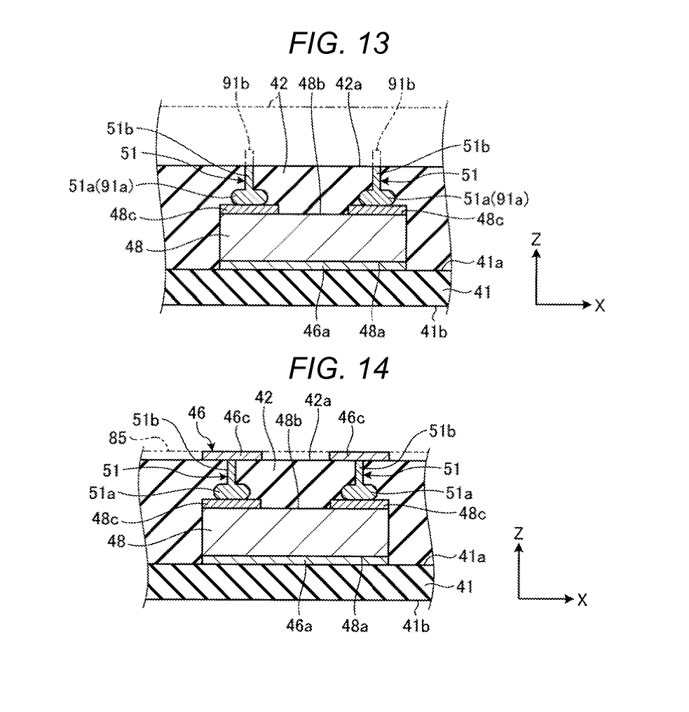

FIG. 13 is a cross-sectional view schematically illustrating the second insulating layer 42 and the stud bump 91 which are ground in the second embodiment. Similar to the first embodiment, in a state where the stud bump 91 bonded to the electrode 48c extends from the electrode 48c of the memory element 48 attached to the first surface 41a of the first insulating layer 41, the softened resin material is supplied onto the first surface 41a. As the resin material is cured, the second insulating layer 42 indicated by a double dot chain line shown in FIG. 13 is formed. As indicated by the double dot chain line, the formed second insulating layer 42 covers the first surface 41a, the memory element 48, and the stud bump 91.

Then, in a state where the memory element 48 and the stud bump 91 are covered by the second insulating layer 42, a part of the second insulating layer 42 is removed by grinding, for example. As the second insulating layer 42 is ground, the third surface 42a is formed in the second insulating layer 42.

A part of the protrusion portion 91b of the stud bump 91, in addition to the second insulating layer 42, is removed by grinding, for example. FIG. 13 shows the removed parts of the second insulating layer 42 and the protrusion portion 91b of the stud bump 91 by double dot chain lines.

As the part of the protrusion portion 91b is removed, the first extension portion 51b of the first wire 51 is formed by the protrusion portion 91b. An end portion of the first extension portion 51b is exposed to the formed third surface 42a. An oxide layer generated in the exposed end portion of the first extension portion 51b is removed by flash etching, for example.

FIG. 14 is a cross-sectional view of the third conductor pattern 46c formed on the third surface 42a of the second insulating layer 42 in the second embodiment. As indicated by a double dot chain line in FIG. 14, the conductor film 85 is formed on the third surface 42a of the second insulating layer 42 by electroplating or non-electroplating, for example. As the conductor film 85 is partially removed by etching, for example, the third conductor pattern 46c is formed.

Then, formation of the third to fifth insulating layers 43 to 45, formation of the second, fourth, fifth, and sixth conductor patterns 46b, 46d, 46e, and 46f, and formation of the first to fourth holes 41c, 43b, 44b, and 45b, and formation of each via 47 are sequentially performed. Through the above-described processes, the storage component 32 shown in FIG. 11 is formed.

As described in the second embodiment, the first wire 51 is not limited to the bonding wire 82 that electrically connects two conductive portions (electrode 48c and first conductor pattern 46a), and may be formed by the stud bump 91 which is electrically connected to one conductive portion (electrode 48c). The second wire 52 may be formed by the stud bump 91 connected to the first conductor pattern 46a.

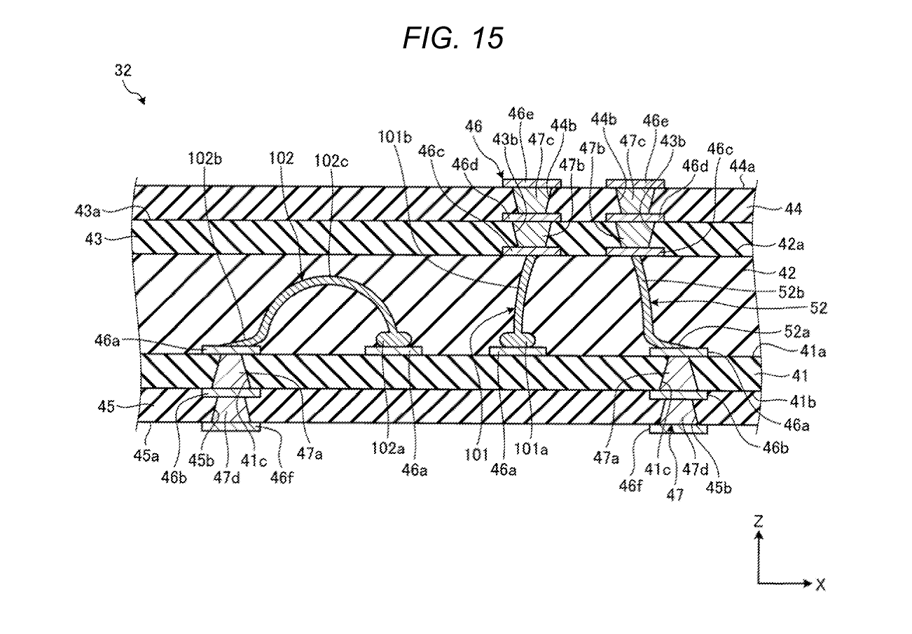

Hereinafter, a third embodiment will be described with reference to FIGS. 15 to 18. FIG. 15 is a cross-sectional view of the storage component 32 according to the third embodiment. As shown in FIG. 15, the storage component 32 according to the third embodiment includes the second wire 52, a third wire 101, and a fourth wire 102.

The third and fourth wires 101 and 102 are examples of a conductive member, and for example, may also be referred to as a wiring member, a connection portion, a conductive portion, a bonding wire, a line member, and a wiring. The third and fourth wires 101 and 102 are bonding wires made of copper, similar to the first and second wires 51 and 52.

The third wire 101 is embedded in the second insulating layer 42. That is, the third wire 101 is provided inside the storage component 32. One end portion of the third wire 101 is electrically connected to the corresponding first conductor pattern 46a. The other end portion of the third wire 101 is electrically connected to the corresponding third conductor pattern 46c. That is, the third wire 101 electrically connects the first conductor pattern 46a and the corresponding third conductor pattern 46c.

The third wire 101 includes a third connection portion 101a and a third extension portion 101b. The third connection portion 101a is an example of a connection portion, and may also be referred to as an end portion, a junction, an adhesive portion, a bonding portion, and a flat portion, for example. The third extension portion 101b is an example of an extension portion, and for example, may also be referred to as a line portion, a protrusion portion, or an intervening portion.

The third connection portion 101a is provided in one end portion of the third wire 101. The third connection portion 101a is formed by so-called first bonding (ball bonding), for example, and has a substantially disc shape. The third connection portion 101a is welded to the first conductor pattern 46a, for example, so as to be bonded to the first conductor pattern 46a. Thus, the third connection portion 101a is electrically connected to the first conductor pattern 46a.

The third extension portion 101b is disposed between the third connection portion 101a and the third conductor pattern 46c. The third extension portion 101b extends from the third connection portion 101a toward the third conductor pattern 46c. An end portion of the third extension portion 101b, which is the other end portion of the third wire 101, is electrically connected to the third conductor pattern 46c.

The third extension portion 101b extends in a direction intersecting with the normal direction of the first surface 41a of the first insulating layer 41. The third extension portion 101b is bent in a curved shape. The third extension portion 101b may be bent in at least one point, or may extend in a linear shape.

The third extension portion 101b is formed in a cylindrical shape having a substantially constant diameter. The third extension portion 101b may be formed in a different shape. In this case, the width of the third extension portion 101b refers to a maximum width of the third extension portion 101b in a direction orthogonal to the direction in which the third extension portion 101b extends.

The diameter of the third extension portion 101b is 20 μm, for example. That is, the diameter of the third extension portion 101b is smaller than the minimum diameters of the first to fourth holes 41c, 43b, 44b, and 45b. Further, the diameter of the third extension portion 101b is smaller than the minimum diameters of the first to fourth vias 47a to 47d. The diameter of the third extension portion 101b is not limited to the above-described value.

The width of the third connection portion 101a is larger than the diameter (width) of the third extension portion 101b. The width of the third connection portion 101a refers to a maximum width of the third connection portion 101a in a direction (XY plane) orthogonal to a thickness direction (direction along the Z-axis) of the third connection portion 101a. The third connection portion 101a is formed to be flat compared with the third extension portion 101b. A contact area between the third connection portion 101a and the first conductor pattern 46a may be larger than a cross-sectional area of the third extension portion 101b orthogonal to the direction where the third extension portion 101b extends.

The fourth wire 102 is embedded in the second insulating layer 42. That is, the fourth wire 102 is provided within the storage component 32. One end portion of the fourth wire 102 is electrically connected to the corresponding first conductor pattern 46a. The other end portion of the fourth wire 102 is electrically connected to another corresponding first conductor pattern 46a. That is, the fourth wire 102 electrically connects two first conductor patterns 46a. One first conductor pattern 46a that is electrically connected by the fourth wire 102 is an example of a first conductor portion, and the other second conductor pattern 46b is an example of a second conductor portion.

The fourth wire 102 includes a fourth connection portion 102a, a fifth connection portion 102b, and a fourth extension portion 102c. The fourth and fifth connection portions 102a and 102b are examples of a connection portion, and may also be referred to as an end portion, a junction, an adhesive portion, a bonding portion, and a flat portion, for example. The fourth extension portion 102c is an example of an extension portion, and for example, may also be referred to as a line portion, a protrusion portion, or an intervening portion.

The fourth connection portion 102a is provided in one end portion of the fourth wire 102. The fourth connection portion 102a is formed by so-called first bonding (ball bonding), for example, and has a substantially disc shape. The fourth connection portion 102a is welded to the first conductor pattern 46a, for example, so as to be bonded to the first conductor pattern 46a. Thus, the fourth connection portion 102a is electrically connected to the first conductor pattern 46a.

The fifth connection portion 102b is provided in the other end portion of the fourth wire 102. The fifth connection portion 102b is formed by so-called second bonding (stitch bonding), for example, and has a substantially flat shape. The fifth connection portion 102b is welded to the other first conductor pattern 46a, for example, to be bonded to the other first conductor pattern 46a. Thus, the fifth connection portion 102b is electrically connected to the other first conductor pattern 46a.

The fourth extension portion 102c is disposed between the fourth connection portion 102a and the fifth connection portion 102b. In other words, the fourth extension portion 102c is disposed between the fourth connection portion 102a and the first conductor pattern 46a. The fourth extension portion 102c extends from the fourth connection portion 102a toward the fifth connection portion 102b.

The fourth extension portion 102c extends in a direction intersecting with the normal direction of the first surface 41a of the first insulating layer 41. The fourth extension portion 102c is bent in a curved shape. The fourth extension portion 102c may be bent in at least one point, or may extend in a linear shape.

The fourth extension portion 102c is formed in a cylindrical shape having a substantially constant diameter. The fourth extension portion 102c may be formed in a different shape. In this case, the width of the fourth extension portion 102c refers to a maximum width of the fourth extension portion 102c in a direction orthogonal to the direction where the fourth extension portion 102c extends.

The diameter of the fourth extension portion 102c is 20 μm, for example. That is, the diameter of the fourth extension portion 102c is smaller than the minimum diameters of the first to fourth holes 41c, 43b, 44b, and 45b. Further, the diameter of the fourth extension portion 102c is smaller than the minimum diameters of the first to fourth vias 47a to 47d. The diameter of the fourth extension portion 102c is not limited to the above-described value.

The width of the fourth connection portion 102a is larger than the diameter (width) of the fourth extension portion 102c. Further, the width of the fifth connection portion 102b is larger than the diameter (width) of the fourth extension portion 102c. The widths of the fourth and fifth connection portions 102a and 102b refer to maximum widths of the fourth and fifth connection portions 102a and 102b in a direction (XY plane) orthogonal to a thickness direction (direction along the Z-axis direction) of the fourth and fifth connection portions 102a and 102b. In this way, the fourth and fifth connection portions 102a and 102b are formed to be flat compared with the fourth extension portion 102c.

A contact area between the fourth connection portion 102a and the first conductor pattern 46a may be larger than a cross-sectional area of the fourth extension portion 102c orthogonal to the direction in which the fourth extension portion 102c extends. Similarly, a contact area between the fifth connection portion 102b and the first conductor pattern 46a may be larger than a cross-sectional area of the fourth extension portion 102c orthogonal to the direction in which the fourth extension portion 102c extends.

Hereinafter, a part of a manufacturing method of the storage component 32 according to the third embodiment will be described. The storage component 32 is not limited to the method which will be described below, and may be manufactured through a different method.

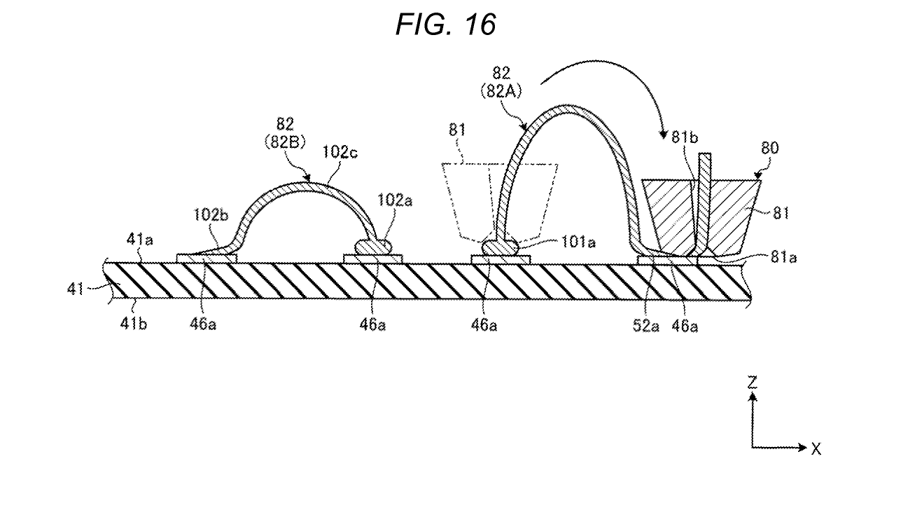

FIG. 16 is a cross-sectional view of the first insulating layer 41 where the wire bonding according to the third embodiment is performed. The first conductor pattern 46a and another first conductor pattern 46a formed on the first insulating layer 41 are electrically connected to each other by the wire bonding.

As shown in FIG. 16, the wire bonding between one first conductor pattern 46a and another first conductor pattern 46a is performed by the capillary 81 of the wire bonding device 80. One end portion of the bonding wire 82 is bonded to one first conductor pattern 46a by first bonding (ball bonding). The other end portion of the bonding wire 82 is bonded to another first conductor pattern 46a by second bonding (stitch bonding).

Two bonding wires 82 shown in FIG. 16 may be individually referred to as bonding wires 82A and 82B in the following description. In the direction along the Z-axis, one bonding wire 82A is higher than the other bonding wire 82B, and protrudes from the first surface 41a of the first insulating layer 41.

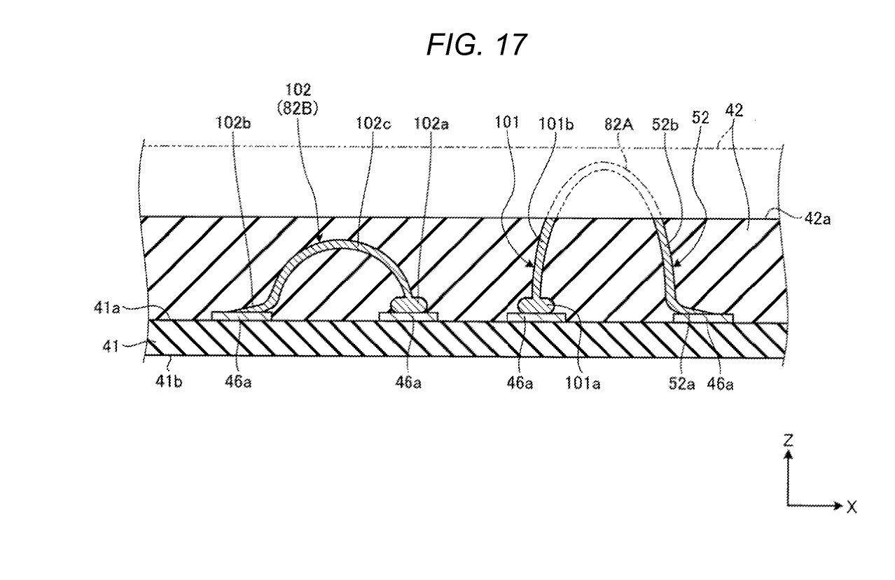

FIG. 17 is a cross-sectional view of the second insulating layer 42 and the bonding wire 82 which are ground in the third embodiment. Similar to the first embodiment, in a state where the bonding wire 82 bonded to the first conductor pattern 46a extends from the first conductor pattern 46a formed on the first surface 41a of the first insulating layer 41, the softened resin material is supplied onto the first surface 41a. As the resin material is cured, the second insulating layer 42 indicated by a double dot chain line in FIG. 17 is formed. As indicated by the double dot chain line, the formed second insulating layer 42 covers the first surface 41a and the bonding wires 82.

Then, in a state where the bonding wire 82 is covered with the second insulating layer 42, a part of the second insulating layer 42 is removed by grinding, for example. As the second insulating layer 42 is ground, the third surface 42a is formed in the second insulating layer 42.

A part of the bonding wire 82A, in addition to the second insulating layer 42, is removed by grinding. FIG. 17 shows the removed parts of the second insulating layer 42 and the bonding wire 82A by double dot chain lines. As the part of the bonding wire 82A is removed, the second wire 52 and the third wire 101 are formed by the bonding wire 82.

An end portion of the second extension portion 52b of the first wire 51 and an end portion of the third extension portion 101b of the third wire 101 are exposed to the formed third surface 42a. Oxide layers generated in the end portions of the exposed second and third extension portions 52b and 101b are removed by flash etching, for example.

On the other hand, the bonding wire 82B is not ground, and remains a state of being covered by the second insulating layer 42. The bonding wire 82B forms the fourth wire 102. Even in a state where the third surface 42a is formed in the second insulating layer 42, the fourth wire 102 electrically connects the first conductor pattern 46a to another first conductor pattern 46a.

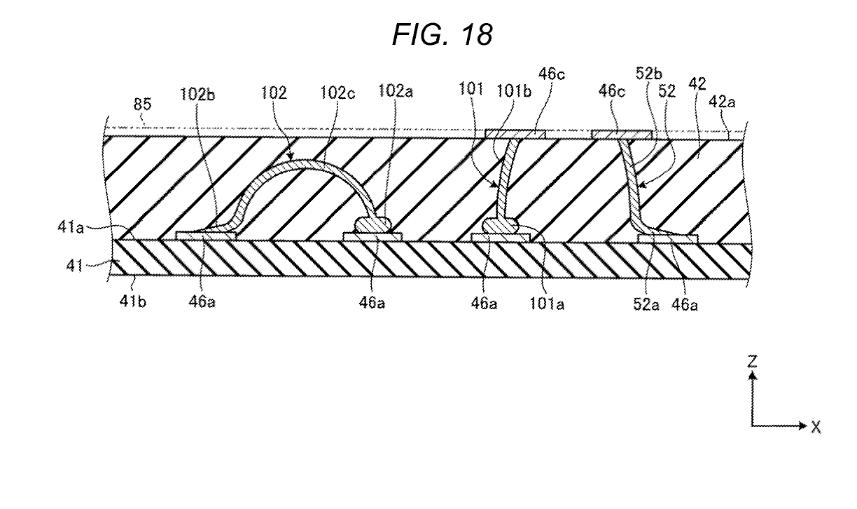

FIG. 18 is a cross-sectional view of the third conductor patterns 46c formed on the third surface 42a of the second insulating layer 42 according to the third embodiment. As indicated by a double dot chain line in FIG. 18, the conductor film 85 is formed on the third surface 42a of the second insulating layer 42 by electroplating or non-electroplating, for example. As the conductor film 85 is partially removed by etching, for example, the third conductor pattern 46c is formed.

Then, formation of the third to fifth insulating layers 43 to 45, formation of the second, fourth, fifth, and sixth conductor patterns 46b, 46d, 46e, and 46f, and formation of the first to fourth holes 41c, 43b, 44b, and 45b, and formation of each via 47 are sequentially performed. Through the above-described processes, the storage component 32 in FIG. 15 is formed.

As described in the third embodiment, the second wire 52 and the third wire 101 may be formed by the bonding wire 82A that electrically connects two first conductor patterns 46a. Further, the fourth wire 102 that electrically connects two first conductor patterns 46a may be formed by the bonding wire 82B embedded in the second insulating layer 42.

According to at least one of the above-described embodiments, the conductive member embedded in the second insulating layer electrically connects the first conductor portion to the second conductor portion, and includes the connection portion bonded to the first conductor portion and the extension portion disposed between the connection portion and the second conductor portion. In this way, since the conductors are connected by the connection portion, for example, compared with a case where a via or a post for interlayer connection is formed, the manufacturing time and manufacturing cost of the board can be reduced.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

For example, the above-described plural embodiments, the storage component 32 is an example of a board. However, a different board such as the circuit board 21 of the SSD 18, the module board 31 of the storage module 22, and a mother board accommodated in the portable computer 10 may be used as the board.

What is claimed is:

1. An electronic device comprising:
an insulating layer;
a first conductor portion disposed in the insulating layer;
a second conductor portion disposed on a surface of the insulating layer; and
a wiring member disposed entirely within the insulating layer and electrically connecting the first conductor portion and the second conductor portion, wherein
the wiring member includes a connection portion welded to the first conductor portion and an extension portion extending from the connection portion to the second conductor portion.

2. The electronic device according to claim 1, wherein
a width of the connection portion is greater than a width of the extension portion.

3. The electronic device according to claim 1, wherein
an area of the connection portion that is in contact with the first conductor portion is greater than a cross sectional area of the extension portion along a surface direction of the insulating layer.

4. The electronic device according to claim 1, wherein
a thickness of the insulating layer is greater than a maximum width of the connection portion.

5. The electronic device according to claim 1, wherein
the extension portion extends in a direction different from a direction that is perpendicular with respect to a surface of the insulating layer.

6. The electronic device according to claim 1, wherein
the second conductor portion and the wiring member are made of metal including copper.

7. The electronic device according to claim 1, wherein
the connection portion is a ball bonding portion.

8. The electronic device according to claim 1, wherein
the connection portion is a stitch bonding portion.

9. The electronic device according to claim 1, further comprising:
a third conductor portion disposed in the insulating layer;
a fourth conductor portion disposed on the surface of the insulating layer; and
a second wiring member disposed entirely within the insulating layer and electrically connecting the third conductor portion and the fourth conductor portion, wherein
the second wiring member includes a second connection portion welded to the third conductor portion and a second extension portion extending from the second connection portion to the fourth conductor portion.

10. The electronic device according to claim 9, wherein
the connection portion of the wiring member is a ball bonding portion, and
the second connection portion of the second wiring member is a stitch bonding portion.

11. The electronic device according to claim 9, wherein the electrically connected structure further includes:
a base insulating layer on which the insulating layer is disposed;
a fifth conductor portion disposed on a surface of the base insulating layer that is apart from the insulating layer; and
a via extending through the base insulating layer and electrically connecting the third conductor portion and the fifth conductor portion, wherein
a crystalline structure of the second wiring member is different from a crystalline structure of the via.

12. A method for manufacturing an electrically connected structure of an electronic device, the method comprising:
forming a first conductor portion;
forming a wiring member on the first conductor portion, such that the wiring member has a connection portion welded to the first conductor portion and an extension portion extending from the connection portion;
forming an insulating layer so as to cover the first conductor portion and the wiring member;
grinding the insulating layer, such that a cross sectional surface of the wiring member is exposed on a ground surface of the insulating layer; and
forming a second conductor portion on the cross sectional surface of the wiring member.

13. The method according to claim 12, wherein
a width of the connection portion is greater than a width of the extension portion.

14. The method according to claim 12, wherein
an area of the connection portion that is in contact with the first conductor portion is greater than a cross sectional area of the extension portion along a surface direction of the insulating layer.

15. The method according to claim 12, wherein
the extension portion extends in a direction different from a direction that is perpendicular with respect to a surface of the insulating layer.

16. The method according to claim 12, wherein
the second conductor portion and the wiring member are made of metal including copper.

17. The method according to claim 12, wherein
the connection portion is a ball bonding portion.

18. The method according to claim 12, wherein
the connection portion is a stitch bonding portion.

19. The method according to claim 12, the method further comprising:
forming a third conductor portion before the wiring member is formed;
bonding the wiring member extending from the first conductor portion to the third conductor portion; and
forming a fourth conductor portion on the ground surface of the insulating layer,

20. The method according to claim 19, wherein
the insulating layer is ground, such that first and second cross sectional surfaces of the wiring member is exposed on the grounded surface of the insulating layer, and
the second conductor portion is formed on the first cross sectional surface of the wiring member, and the fourth conductor portion is formed on the second cross sectional surface of the wiring member.
